(19) United States
(12) Patent Application Publication
(10) Pub. No.: US 2026/0358454 A1
(43) Pub. Date: Nov. 12, 2026

(54) DEVICE FOR PARAMETERISING A PROBE HAVING TWO SEALED ENCLOSURES AND USE THEREOF IN THE FIELD OF LOW-TEMPERATURE NUCLEAR MAGNETIC RESONANCE (NMR)SPECTROSCOPY ANALYSIS

(71) Applicant: COMMISSARIAT A L'ENERGIE ATOMIQUE ET AUX ENERGIES ALTERNATIVES, Paris (FR)

(72) Inventors: Eric BOULEAU, Grenoble Cedex 09 (FR); Gaël DE PAËPE, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/125,121

(22) PCT Filed: Nov. 7, 2023
(86) PCT No.: PCT/EP2023/081003

§ 371 Date: Apr. 28, 2025

(30) Foreign Application Priority Data
Nov. 8, 2022 (FR) FR2211622

(51) Int. Cl. G01R 33/46; G01R 33/31; G01R 33/36

(52) U.S. Cl. CPC G01R 33/46; G01R 33/31; G01R 33/3628

(57) ABSTRACT

A device includes a sealed enclosure having a sheath that opens onto the outside of the sealed enclosure, a cryogenic chamber arranged in the sealed enclosure and including an opening that opens into the sealed enclosure, an adjusting rod translatably mounted in the cryogenic chamber in order to adjust the positioning of an element accommodated in the cryogenic chamber, a transmission bar that sealingly passes through the sheath and is translatably movable along the longitudinal axis of the sheath by means of an element outside the sheath, the transmission bar being connected to the adjusting rod in order to transmit the translation of the bar to the rod and vice versa, and a corrugated bellows sealingly attached to the transmission bar and around the opening in order to seal the cryogenic chamber.

### TECHNICAL FIELD

The present invention relates to systems having two enclosures, in particular systems comprising a low-temperature chamber, known as a cryogenic chamber, contained in a hermetically sealed vacuum enclosure.

Although described for use in the field of nuclear magnetic resonance (NMR) spectroscopy, the present invention can be implemented for any system having two hermetically sealed enclosures, that is for any system comprising one hermetically sealed enclosure arranged inside another hermetically sealed enclosure.

### PRIOR ART

Nuclear magnetic resonance (NMR) spectroscopy is a non-destructive analysis method using the phenomenon of nuclear magnetic resonance (NMR), in particular for analyzing molecular structures. NMR occurs when atomic nuclei with a non-zero spin are placed in a static magnetic field and excited by electromagnetic radiation. This method is particularly used in organic chemistry, inorganic chemistry, biology and materials science.

In solid-state NMR spectroscopy, it is usual to place the sample to be analyzed on a rotor in order to rotate it about an axis inclined by 54°44′, known as the magic angle, relative to the static magnetic field.

It is also known that increasing the intensity of the magnetic field, increasing the speed of the rotor, and/or using the dynamic nuclear polarization (DNP) phenomenon make it possible to improve the sensitivity and resolution of NMR spectroscopy.

It has been proved that, during NMR analysis, the lower the temperature, the greater the signal-to-noise ratio and the higher the gain due to the DNP phenomenon. High-resolution NMR spectrometers thus generally operate at low temperature, in particular around 100 K. Article [1] describes an NMR spectrometer using the DNP phenomenon and operating at temperatures below 100 K.

In order to obtain low temperatures, for example around or less than 100 K, it is preferable for the NMR spectrometer to operate autonomously and in a closed loop. A device that operates autonomously is a device that does not require a cryogenic fluid supply. A device that operates in a closed loop is a device in which a working fluid circulates without exposure to the external environment and without fluid transfer outside the loop.

In an autonomous, closed-loop NMR spectrometer, it is important to maintain high purity of the working fluid, that is it must be as free as possible from impurities of any type (gaseous, solid in the form of particles, hydrocarbon-based, etc.).

NMR spectrometers that operate autonomously and in a closed loop generally comprise a probe having two sealed enclosures, that is comprising a hermetically sealed vacuum enclosure, for example at a pressure less than or equal to 10⁻⁵ mbar, and a sealed chamber, arranged in the hermetically sealed enclosure, that is pressurized, for example to 4 bar, and at cryogenic temperature, for example around or even less than 100 K. This arrangement of the cryogenic chamber in the hermetically sealed vacuum enclosure ensures excellent thermal insulation and therefore makes it possible to carry out NMR spectrometry at low or very low temperature.

In addition, the magnetic field of the NMR spectrometer can be modified slightly as a function of the atomic nucleus of the material to be analyzed. To this end, the probe comprises a plurality of components known as tuning capacitors, which are housed in the cryogenic chamber. Each of the tuning capacitors comprises a movable core that makes it possible to precisely adjust the impedance of a coil of the probe as a function of the position of the core in the coil.

The arrangement of the tuning capacitors in the cryogenic chamber of the probe makes them difficult to access and therefore makes the adjustment thereof complex.

Likewise, in such NMR spectrometers, the stator, which makes it possible to rotate the sample mounted on a rotor inclined at the magic angle, is arranged in the sealed cryogenic chamber of the probe. The stator is therefore difficult to access.

One method envisaged for adjusting the tuning capacitors and/or the angle of inclination of the stator consists in dismantling and then reassembling, at ambient temperature, the hermetically sealed enclosure and the cryogenic chamber. Such a method is painstaking and time-consuming, and requires the purification of the cryogenic chamber after reassembly in order for the NMR spectrometer to operate autonomously and in a closed loop. In addition, such a method is also complex to implement as it requires the anticipation of the electronic and mechanical modifications to the tuning capacitors and/or the stator caused by the descent to very low temperature.

There is therefore a need for a device that makes it possible to easily and quickly adjust the tuning capacitors and/or the angle of inclination of the stator of an NMR spectrometer comprising a probe having two hermetically sealed enclosures.

More generally, there is a need for a device suitable for easily and quickly adjusting and moving elements housed in a chamber operating at cryogenic temperatures, itself arranged in a hermetically sealed enclosure.

The aim of the invention is to at least partially meet this need/these needs.

### DISCLOSURE OF THE INVENTION

To this end, the invention relates to a device comprising:
a hermetically sealed enclosure comprising at least one sheath emerging outside the hermetically sealed enclosure,
a cryogenic chamber arranged in the hermetically sealed enclosure and comprising at least one opening emerging in the hermetically sealed enclosure,
at least one adjusting rod translatably mounted in the cryogenic chamber in order to adjust the positioning of an element housed in the cryogenic chamber,
at least one transmission bar that sealingly passes through the sheath, the transmission bar being translatably movable along the longitudinal axis of the sheath by an element arranged outside the sheath, the transmission bar being connected to the adjusting rod so that the translation of the bar is transmitted to the rod and vice versa,
at least one corrugated bellows sealingly fastened to the transmission bar and around the opening in order to hermetically close the cryogenic chamber.

Preferably, the sheath comprises a gland configured to be sealingly compressed on the transmission bar while allowing it to move translatably.

Preferably, the gland comprises at least one, preferably at least two, seal(s), and clamping rings, the clamping ring(s) being configured to compress the seal(s) on the transmission bar.

Preferably, the gland comprises an annular chamber in which the seal(s) is(are) partially housed, the annular chamber being at a pressure less than or equal to 1.10⁻³ mbar.

Preferably, the sheath comprises a guide sleeve configured to guide the translation of the transmission bar, and at least one immobilizing means for preventing the rotation of the transmission bar.

Preferably, the device comprises a thumb wheel accessible from outside the sheath and a conversion mechanism configured to convert the rotation of the thumb wheel into a translation of the transmission bar along the axis of the sheath. Preferably, the transmission bar comprises a threaded portion and the conversion mechanism comprises a nut or a toothed wheel in order to form, with the threaded portion, a jackscrew or a rack and pinion system respectively.

Preferably, the device comprises ball bearings configured to facilitate the rotation of the thumb wheel.

The thumb wheel can be rotated manually and/or by a motor. The conversion mechanism can comprise a reduction gear configured to transmit the rotation of the thumb wheel into an output rotation, the ratio between the output rotating speed and the rotating speed of the thumb wheel being less than 1:15, the conversion mechanism being configured to convert the output rotation into a translation of the transmission bar.

Preferably, the corrugated bellows is made from metal.

Preferably, the corrugated bellows is hermetically welded to the transmission bar.

Preferably, the device comprises an annular seal sealing the fastening of the corrugated bellows around the opening.

According to a first alternative, the device can comprise a transmission cable one end of which is fastened to the transmission bar and the other end of which is fastened to the adjusting rod.

Preferably, the device comprises a guide tube configured to guide the sliding of the transmission cable. Preferably, the guide tube extends along a curve, preferably in the shape of an S.

Preferably, the device comprises a return spring mounted around and fastened to the adjusting rod in order to cause it to translate toward the inside of the cryogenic chamber when the cable is slackened by a translation of the transmission bar toward the inside of the cryogenic chamber.

According to a second alternative, the adjusting rod can be fastened directly to the transmission bar.

Preferably, the device comprises at least one tuning capacitor arranged in the cryogenic chamber, the tuning capacitor comprising a core that can move translatably in order to vary the tuning capacitor, the opposite end of the adjusting rod from the end connected to the transmission bar being connected, preferably fastened, to the core.

Preferably, the device comprises a stator arranged in the cryogenic chamber and rotatably mounted about a transverse axis, the adjusting rod being connected, preferably fastened, to the stator so that the translation of the adjusting rod rotates the stator about the transverse axis.

Preferably, the hermetically sealed enclosure is at a pressure of less than 10⁻⁵ mbar.

Preferably, the cryogenic chamber is at a pressure of between 1000 and 4000 mbar and/or a temperature of less than 30 K.

Preferably, the device forms a probe of a nuclear magnetic resonance (NMR) spectrometer.

Preferably, the probe comprises a stator and at least one adjusting rod the translation of which modifies the inclination of the stator, and/or at least one adjusting rod the translation of which modifies a tuning capacitor of the probe.

The present invention therefore essentially consists of a device comprising a hermetically sealed enclosure, a cryogenic chamber arranged in the hermetically sealed enclosure, and an adjusting rod for positioning the elements contained in the cryogenic chamber that is connected to a transmission bar accessible from the outside, so that the translation of one causes the translation of the other, and vice versa, even if the connection between them is not rigid. The adjusting rod and the transmission bar are assembled while keeping the cryogenic chamber and the hermetically sealed enclosure sealed, in particular by means of a sealed bellows fastened to the transmission bar. The adjustment of the positioning of the elements contained in the chamber can for example make it possible to select the impedance of a tuning capacitor contained in the cryogenic chamber.

The components for making adjustments from the outside are easy to implement and have a small footprint.

In particular, the bellows, preferably in the form of a corrugated bellows, ensures the sealing of the cryogenic chamber both at ambient temperature and at low temperature, for example a temperature of less than 100 K. The corrugated bellows also ensures sealing despite the pressure and temperature differences between the hermetically sealed enclosure and the cryogenic chamber, which can be significant. In addition, the use of a bellows ensures satisfactory thermal insulation between the hermetically sealed enclosure and the cryogenic chamber.

### BRIEF DESCRIPTION OF THE DRAWINGS

Further advantages and features will become more clearly apparent on reading the detailed description given by way of non-limiting illustration, with reference to the following figures:

FIG. 1 is a schematic longitudinal cross-sectional view of the device according to the invention, the guide tube of the device being straight and the corrugated bellows of the device being subject to an internal pressure greater than the external pressure.

FIG. 2 is a schematic longitudinal cross-sectional view of the device according to the invention, the device being a probe for NMR spectroscopy and the translation of the adjusting rod adjusting the tuning capacitor of the probe.

FIG. 3 is a schematic longitudinal cross-sectional view of the device according to the invention, the device being a probe for NMR spectroscopy and the translation of the adjusting rod adjusting the angle of inclination of the stator of the probe.

FIG. 4 is a schematic longitudinal cross-sectional view of the device according to the invention, the guide tube of the device extending in an S shape and the corrugated bellows of the device working with an internal pressure greater than the external pressure.

FIG. 5 is a schematic longitudinal cross-sectional view of the device according to the invention, the guide tube of the device extending in an S shape and the corrugated bellows of the device working with an internal pressure less than the external pressure.

### DETAILED DESCRIPTION

For reasons of clarity, the various elements in the figures are shown on a free scale, and the actual dimensions of the various parts are not necessarily adhered to.

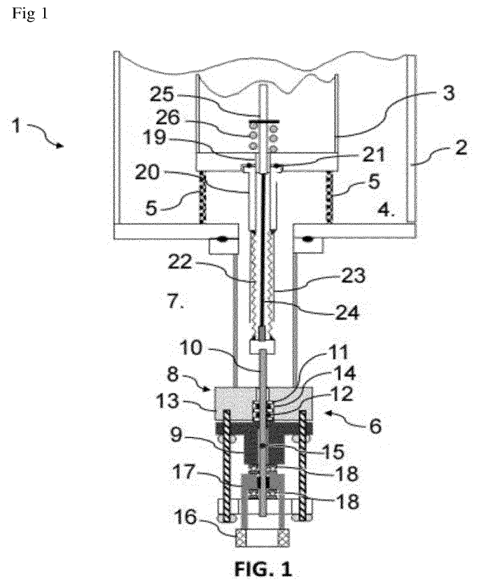

FIG. 1 shows a device 1 according to the invention, comprising a hermetically sealed enclosure 2 and a cryogenic chamber 3 housed in the hermetically sealed enclosure 2.

The internal environment 4 of the hermetically sealed enclosure 2 is at a pressure of less than or equal to 10⁻⁵ mbar.

The cryogenic chamber 3 is sealed, pressurized, for example to 4 bar, and at a cryogenic temperature, for example around or even less than 100 K. This arrangement of the cryogenic chamber 3 in the hermetically sealed enclosure 2 ensures excellent thermal insulation.

Thermally insulating supports 5 support the cryogenic chamber 3 while limiting heat conduction.

The hermetically sealed enclosure 2 comprises a sheath 6 emerging at one end in the external environment 7 of the hermetically sealed enclosure 2 and at the other end in the internal environment 4 of the hermetically sealed enclosure 2. The sheath 6 comprises a gland 8 and a guide sleeve 9.

A transmission bar 10 is inserted into the sheath 6 with the gland 8 compressed around the transmission bar 10 in order to seal the sheath 6. The transmission bar 10 is translatably mounted along the central axis of the sheath.

The gland 8 comprises three clamping rings 11 and two seals 12 housed in a hollow cylindrical structure 13. The inner diameter of the hollow cylindrical structure 13 is sufficient to allow the transmission bar 10 to pass through it. The clamping rings 11 are clamped in order to compress the seals 12 around the transmission bar and thus sealingly close the sheath 6. The compression of the seals 12 reduces the inner diameter thereof, which can thus be smaller than the outer diameter of the transmission bar 10. The compression of the seals 12 can be adjusted using a spring plunger.

The gland 8 also comprises an annular chamber 14 around the clamping rings 11 and the seals 12. The annular chamber 14 is evacuated to a pressure typically less than or equal to 1.10⁻³ mbar. The volume between the clamping rings 11 and the seals 12 and the volume between the two seals 12 is thus at a pressure of less than or equal to 1.10⁻³ mbar. Such a pressure makes it possible to ensure improved compression of the seals 12 and improved sealing of the closure of the sheath 6.

In addition, the transmission bar 10 is prevented from rotating on itself in the guide sleeve 9. To this end, the transmission bar 10 can comprise a pin 15 arranged in a slot made in the guide sleeve 9.

The device 1 comprises a thumb wheel 16 arranged outside the hermetically sealed enclosure 2 and rigidly connected to a nut 17 into which the transmission bar 10 is screwed, forming a screw and nut system. This system 10, 17, similar to a jackscrew, makes it possible to convert the rotation of the thumb wheel 16 into a translation of the transmission bar 10 along the central axis of the sheath. The thumb wheel 16 can be rotated manually or by a motor. Ball bearings 18 are arranged on either side of the nut 17 in order to facilitate the rotation of the thumb wheel 16.

The screw and nut system 10, 17 makes it possible to translate the transmission bar 10 precisely and easily. In addition, such a system ensures that the bar 10 is held in position in the absence of any rotation of the thumb wheel 16.

The cryogenic chamber 3 comprises an opening 19 around which is fastened, preferably screwed, a guide tube 20, in particular straight, which extends into the hermetically sealed enclosure 2.

An annular seal 21 seals the fastening of the guide tube 20 around the opening 19. The annular seal 21 can be a resilient seal with a C-shaped cross section. Alternatively, the annular seal 21 can be formed by a metal wire, for example indium. Indium is particularly suitable for cryogenic temperatures. The annular seal 21 can be compressed between the guide tube 20 and the wall of the cryogenic chamber 3 with a compressive stress of up to 50 N/mm.

The device 1 comprises a corrugated bellows 22 one end of which is sealingly fastened to the guide tube 20. The other end of the corrugated bellows 22 is sealingly fastened around the transmission bar 10 so that the translation of the transmission bar 10 contracts the corrugated bellows 22 in one direction, and extends it in the other direction. The corrugated bellows 22 can be hermetically welded to the transmission bar 10 and/or to the guide tube 20. The welds advantageously ensure improved sealing at low temperatures, for example less than or equal to 100 K, and withstand large pressure and temperature differences.

In the embodiment illustrated in FIG. 1, pushing the transmission bar 10 toward the opening 19 contracts the corrugated bellows 22 and, conversely, pulling the transmission bar 10 toward the outside extends the corrugated bellows 22.

The corrugated bellows 22 hermetically closes the opening 19 and seals the cryogenic chamber 3. The pressure exerted on the inside of the corrugated bellows 22 is equal to the pressure exerted in the cryogenic chamber 3. The pressure exerted on the outside of the corrugated bellows 22 is equal to the pressure of the internal environment 4 of the hermetically sealed enclosure 2.

The corrugated bellows 22 is configured to withstand the difference between the pressure exerted on the inside thereof and the pressure exerted on the outside thereof. In particular, the thickness of the wall of the corrugated bellows 22 can be greater than or equal to 0.1 mm, preferably between 0.05 and 0.012 mm. In addition, such a thickness limits the heat losses by conduction.

By way of example, the corrugated bellows 22 has, in the extended state, a length of 80 mm and a diameter of 16 mm.

The device 1 also comprises a duct 23 around the corrugated bellows 22 that is configured to guide the corrugated bellows 22 in its contraction or extension. The duct 23 thus prevents the corrugated bellows 22 from buckling.

The device 1 comprises a cable 24 one end of which is fastened to the transmission bar 10 and the other end of which is fastened to an adjusting rod 25.

The cable 24 is arranged in the corrugated bellows 22 and the guide tube 20. The adjusting rod 25 is arranged in the cryogenic chamber 3 facing the opening 19. The cable 24 thus exerts tension on the adjusting rod 25 when the transmission bar 10 is pulled toward the outside of the hermetically sealed enclosure 2.

The device 1 comprises a return spring 26 one end of which is fastened to the cryogenic chamber 3 and the other end of which extends around and is fastened to the adjusting rod 25. The return spring 26 makes it possible to keep the cable 24 tensioned when the transmission bar 10 is pushed toward the cryogenic chamber 3. Such pushing slackens the cable 24, and the force of the return spring 26 tensions the cable 24 again and simultaneously pushes the adjusting rod 25.

The cable 24 and the return spring 26 thus transmit any translation of the transmission bar 10 along the axis of the sheath into a translation of the adjusting rod 25. As will be seen below, the translation of the adjusting rod 25 in the cryogenic chamber 3 makes it possible to precisely position elements contained in the cryogenic chamber 3.

The cable 24 is preferably made from a metal material. Preferably, the cable 24 is multi-strand, and thus has great flexibility, which facilitates the movement thereof in the corrugated bellows 22 and the guide tube 20.

In order to limit the heat losses by conduction, the cable 24 can have a diameter of less than or equal to 1 mm, preferably between 0.8 and 1.2 mm.

In order to ensure satisfactory thermal and electric insulation, the adjusting rod 25 can be made from epoxy glass.

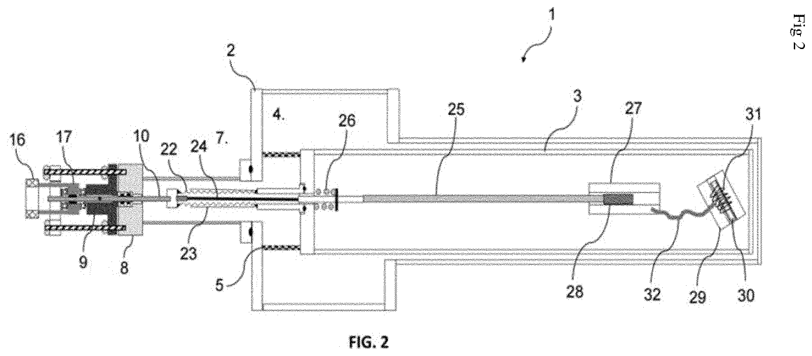

FIG. 2 shows a device 1 according to the invention, forming a probe for NMR spectroscopy.

In addition to the elements of the device 1 described with reference to FIG. 1, the probe 1 comprises a tuning capacitor 27 arranged in the cryogenic chamber 3. The tuning capacitor 27 comprises a core 28 translatably mounted in a housing in order to vary the impedance of the tuning capacitor 27.

The housing of the tuning capacitor 27 is cylindrical, with a length of 60 mm and a diameter of 12 mm.

The adjusting rod 25 is fastened, at the opposite end thereof from the cable 24, to the core 28. The translation of the adjusting rod 25 thus translates the core 28 in the housing of the tuning capacitor 27 and thus adjusts the impedance of the tuning capacitor 27. In other words, with the transmission mechanism described, the impedance of the tuning capacitor 27 can be modified simply by turning the thumb screw 16 on itself.

By way of example, the adjusting rod 25 can translate by 0.7 mm per complete revolution of the thumb screw 16 on itself.

The probe 1 also comprises a stator 29 in which is arranged a rotor 30 for NMR spectroscopy. The stator 29 comprises a coil 31 connected to the tuning capacitor 27 by an electrical lead 32. The coil 31 is configured to generate a static magnetic field for NMR spectroscopy. Varying the impedance of the tuning capacitor 27 modifies the static magnetic field generated by the coil 31. It is thus possible to tune the static magnetic field during NMR spectroscopy of a sample contained in the rotor 30 as a function of the atomic nucleus of the material to be analyzed.

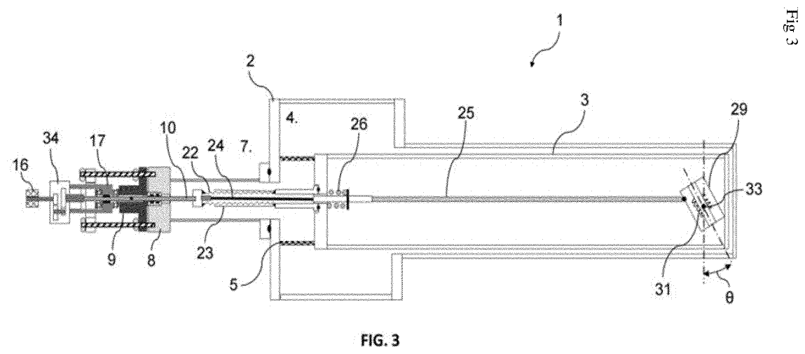

FIG. 3 also shows a probe 1 for NMR spectroscopy, according to the invention. The probe 1 differs from the device 1 illustrated in FIG. 1 in that it comprises a staged reduction gear 34 arranged between the thumb wheel 16 and the nut 17.

The reduction gear 34 transmits the rotation of the thumb wheel 16 into an output rotation with a reduction ratio of less than 1:15, for example 1:19.

In a similar manner to a jackscrew, the nut 17 and the transmission bar 10 convert the output rotation into a translation of the transmission bar 10 along the axis of the sheath.

The reduction gear 34 therefore enables the precise adjustment of the translation of the transmission bar 10, and consequently of the adjusting rod 25.

By way of example, with a reduction gear 34, the adjusting rod 25 can translate by 0.037 mm per complete revolution of the thumb screw 16 on itself.

The probe 1 also comprises a stator 29 for receiving a rotor 30 for NMR spectroscopy. The stator 29 comprises a coil 31 configured to generate a static magnetic field for NMR spectroscopy.

The stator 29 is rotatably mounted about its transverse axis 33. The adjusting rod 25 is fastened, at the opposite end thereof from the cable 24, to the stator 29, so that the translation of the adjusting rod 25 rotates the stator 29 about its transverse axis 33. With the transmission mechanism described, the angle of inclination θ of the stator 29 can thus be adjusted by turning the thumb screw 16 on itself. The angle of inclination θ of the stator 29 corresponds to the angle between the longitudinal axis along which the stator 29 extends and the static magnetic field for NMR spectroscopy.

By way of example, a complete revolution of the thumb screw 16 on itself corresponds to a rotation of 00°04′42″ of the angle of inclination θ of the stator 29. The probe 1 is therefore suitable for precisely adjusting the angle of inclination θ of the stator 29 to 54°44′.

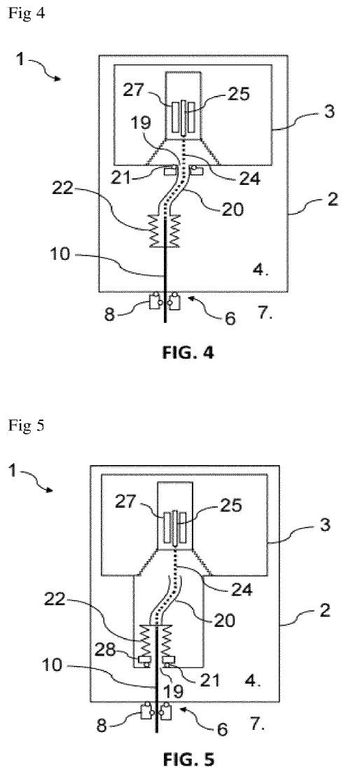

FIG. 4 shows a device 1 according to the invention. It differs from the device illustrated in FIG. 2 in that the guide tube 20 is not straight, but extends in an S shape, which makes it possible to reduce the footprint thereof. In addition, this offsets the translations of the transmission bar 10 and the adjusting rod 25, which reduces the space necessary for said translations.

FIG. 5 shows a device 1 according to the invention. It differs from the device illustrated in FIG. 4 in that it is not the guide tube 20 that is fastened around the opening 19, but the corrugated bellows 22, one end of which is fastened around the opening 19, extending into the cryogenic chamber 3. A flange 28 arranged at the end of the corrugated bellows 22 squeezes the annular seal 21 in order to seal the fastening of the corrugated bellows 22 around the opening 19. The other end of the corrugated bellows 22 is fastened, preferably welded, to the transmission bar 10 and to the guide tube 20. The guide tube 20 extends in an S shape in the cryogenic chamber 3.

The corrugated bellows 22 thus hermetically closes the opening 19 and seals the cryogenic chamber 3. The pressure exerted on the inside of the corrugated bellows 22 is equal to the pressure of the internal environment 4 of the hermetically sealed enclosure 2. The pressure exerted on the outside of the corrugated bellows 22 is equal to the pressure exerted in the cryogenic chamber 3.

The embodiment in FIG. 5 is advantageous when the pressure of the internal environment 4 is less than the pressure exerted in the cryogenic chamber 3. The corrugated bellows 22 is stronger and subjected to less mechanical stress when the pressure exerted on the outside thereof is greater than or equal to the pressure exerted on the inside thereof. The wall of the corrugated bellows 22 can thus be thinner than in the embodiments in FIGS. 1 and 2, for example between 0.05 and 0.08 mm. The corrugated bellows 22 is therefore more flexible, which facilitates the contraction and extension thereof and, consequently, the translation of the transmission bar 10.

Other variants and improvements can be envisaged without departing from the scope of the invention.

In particular, the device 1 can comprise a plurality of sheaths 6, an equal number of openings 19, and for each sheath 6 and opening 19, a transmission bar and an adjusting rod connected together in order to translate an element contained in the cryogenic chamber 3. For example, if the device 1 is a probe for NMR spectroscopy, the device 1 can comprise six adjusting rods each configured to adjust one of the tuning capacitors 27 of the probe, and a seventh adjusting rod configured to adjust the angle of inclination θ of the stator 29 of the probe.

### References cited

[1] :Yoh Matsuki and Toshimichi Fujiwara, “Cryogenic Platforms and Optimized DNP sensitivity”, eMagRes, 2018, Vol 7: 9-24.

1. A device comprising:
a hermetically sealed enclosure comprising at least one sheath emerging outside the hermetically sealed enclosure,
a cryogenic chamber arranged in the hermetically sealed enclosure and comprising at least one opening emerging in the hermetically sealed enclosure,
at least one adjusting rod translatably mounted in the cryogenic chamber in order to adjust the positioning of an element housed in the cryogenic chamber,
at least one transmission bar that sealingly passes through the sheath, the transmission bar being translatably movable along the longitudinal axis of the sheath by an element arranged outside the sheath, the transmission bar being connected to the adjusting rod so that the translation of the bar is transmitted to the rod and vice versa,
at least one corrugated bellows sealingly fastened to the transmission bar and around the opening in order to hermetically close the cryogenic chamber.

2. The device as claimed in claim 1, wherein the sheath comprises a gland configured to be sealingly compressed on the transmission bar while allowing it to move translatably.

3. The device as claimed in claim 2, wherein the gland comprises at least one seal, and clamping ring,
the clamping ring being configured to compress the seal on the transmission bar.

4. The device as claimed in claim 1, wherein the sheath comprises a guide sleeve configured to guide the translation of the transmission bar, and at least one immobilizing means for preventing the rotation of the transmission bar.

5. The device as claimed in claim 1, comprising a thumb wheel accessible from outside the sheath and a conversion mechanism configured to convert the rotation of the thumb wheel into a translation of the transmission bar along the axis of the sheath.

6. The device as claimed in claim 1, wherein the corrugated bellows is made from metal.

7. The device as claimed in claim 1, wherein the corrugated bellows is hermetically welded to the transmission bar.

8. The device as claimed in claim 1, comprising an annular seal sealing the fastening of the corrugated bellows around the opening.

9. The device as claimed in claim 1, comprising a transmission cable one end of which is fastened to the transmission bar and the other end of which is fastened to the adjusting rod.

10. The device as claimed in claim 9, comprising a return spring mounted around and fastened to the adjusting rod in order to cause it to translate toward the inside of the cryogenic chamber when the cable is slackened by a translation of the transmission bar toward the inside of the cryogenic chamber.

11. The device as claimed in claim 1, comprising at least one tuning capacitor arranged in the cryogenic chamber, the tuning capacitor comprising a core that can move translatably in order to vary the tuning capacitor, the opposite end of the adjusting rod from the end connected to the transmission bar being connected to the core.

12. The device as claimed in claim 1, comprising a stator arranged in the cryogenic chamber and rotatably mounted about a transverse axis, the adjusting rod being connected to the stator so that the translation of the adjusting rod rotates the stator about the transverse axis.

13. The device as claimed in claim 1, wherein the hermetically sealed enclosure is at a pressure of less than 10−5 mbar.

14. The device as claimed in claim 1, wherein the cryogenic chamber is at a pressure of between 1000 and 4000 mbar and/or a temperature of less than 30 K.

15. The device as claimed in claim 1, forming a probe of nuclear magnetic resonance (NMR) spectrometer.
